(19) United States
(12) Patent Application Publication
(10) Pub. No.: US 2015/0041823 A1
(43) Pub. Date: Feb. 12, 2015

(54) LED DIE AND METHOD OF MANUFACTURING THE SAME

(71) Applicant: ADVANCED OPTOELECTRONIC TECHNOLOGY, INC., Hsinchu Hsien 303 (TW)

(72) Inventors: CHING-HSUEH CHIU, Hukou (TW); YA-WEN LIN, Hukou (TW); PO-MIN TU, Hukou (TW); SHIH-CHENG HUANG, Hukou (TW)

(21) Appl. No.: 14/456,344

(22) Filed: Aug. 11, 2014

(30) Foreign Application Priority Data
Aug. 12, 2013 (CN) 2013103477022

(51) Int. Cl. H01L 33/32; H01L 33/00

(52) U.S. Cl. CPC H01L 33/32; H01L 33/0075
USPC 257/76; 438/46

(57) ABSTRACT

An LED die includes a substrate, a first buffer layer, a second buffer layer, a plurality of nanospheres, a first semiconductor layer, an active layer and a second semiconductor layer. The first buffer layer, the second buffer layer, the first semiconductor layer, the active layer and the second semiconductor layer are formed successively on the substrate. The substrate has a plurality of protrusions formed on a surface thereof. The nanospheres are located on the first buffer layer formed on the protrusions and covered by the second buffer layer. The present disclosure also provides a method of manufacturing an LED die.

### CROSS-REFERENCE TO RELATED APPLICATIONS

This application claims priority to Chinese Patent Application No. 201310347702.2 filed on Aug. 12, 2013 in the State Intellectual Property Office Of The P. R. C, the contents of which are incorporated by reference herein.

### FIELD

The disclosure relates to an LED (light emitting diode) die and a method of manufacturing the LED die.

### BACKGROUND

An LED die typically includes a substrate for crystal growth, which has an effect for a performance of an LED die.

### BRIEF DESCRIPTION OF THE DRAWINGS

Implementations of the present technology will now be described, by way of example only, with reference to the attached figures.

FIG. 1 is a flowchart of a method of manufacturing an LED die in accordance with an exemplary embodiment of the present disclosure.

FIGS. 2-7 are schematic cross sections showing semi-finished LED dies processed by different steps of the method of FIG. 1 in accordance with an embodiment of the present disclosure.

FIG. 8 is a cross section showing a light path diagram of the LED die obtained by the method of FIG. 1.

### DETAILED DESCRIPTION OF EMBODIMENTS

It will be appreciated that for simplicity and clarity of illustration, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The only drawing is not necessarily to scale and the proportions of certain parts have been exaggerated to better illustrate details and features of the present disclosure. The description is not to be considered as limiting the scope of the embodiments described herein.

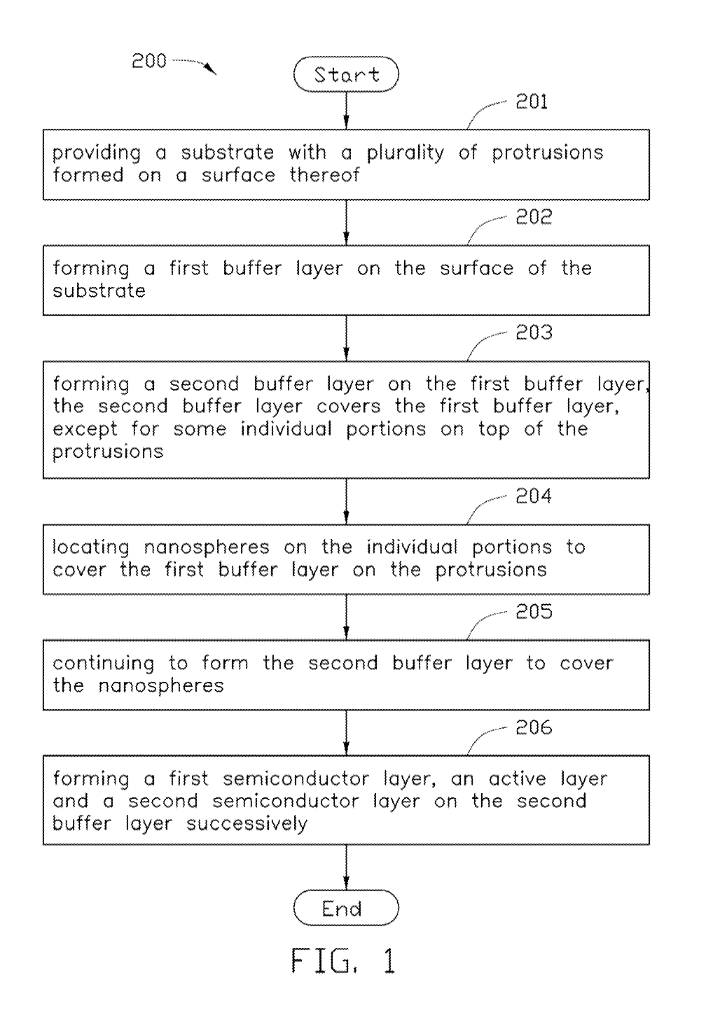

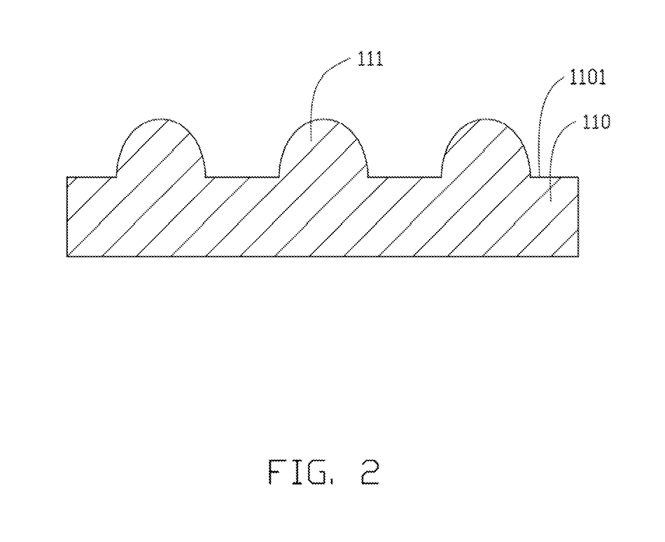

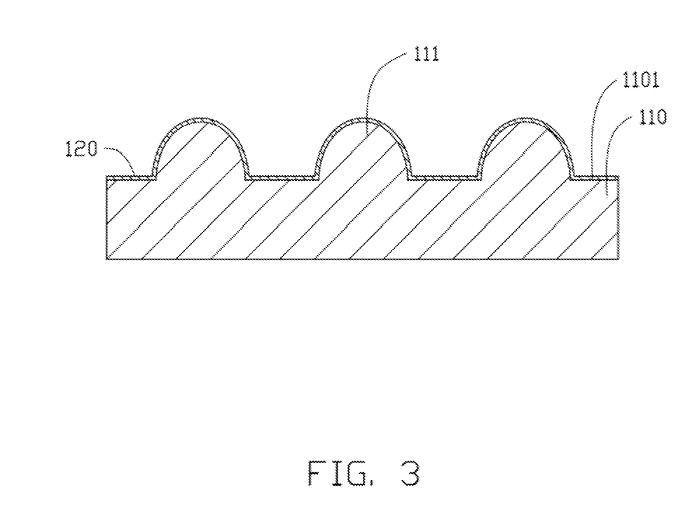

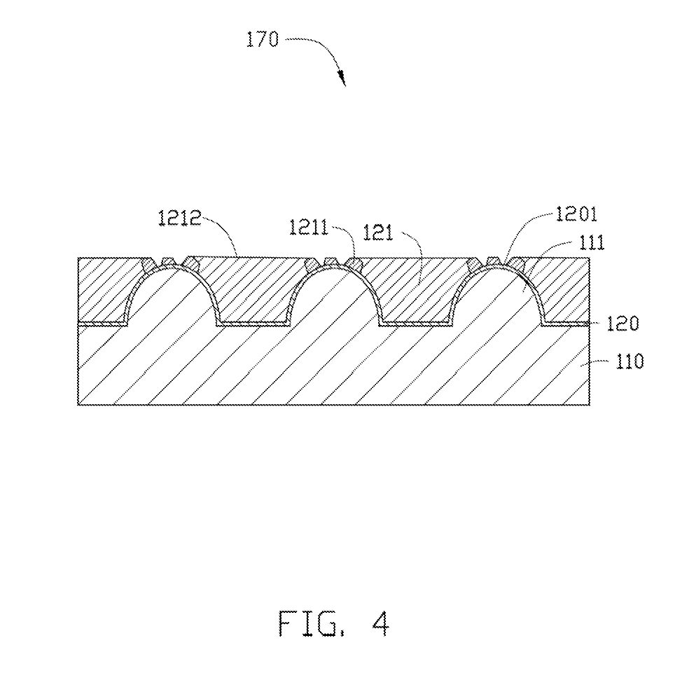

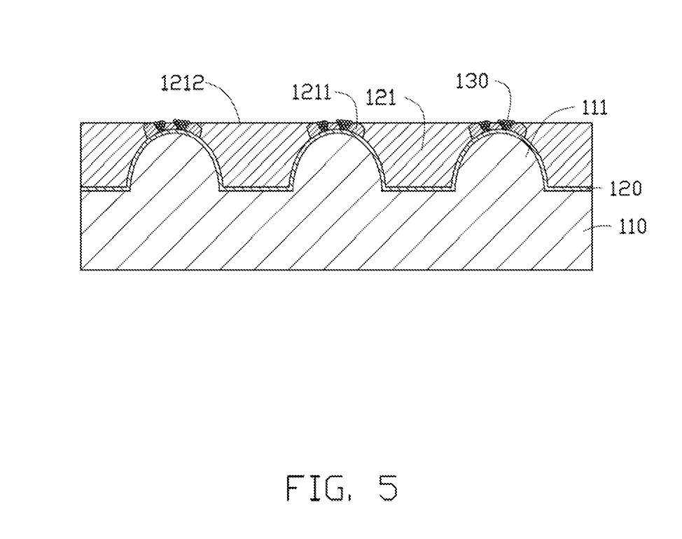

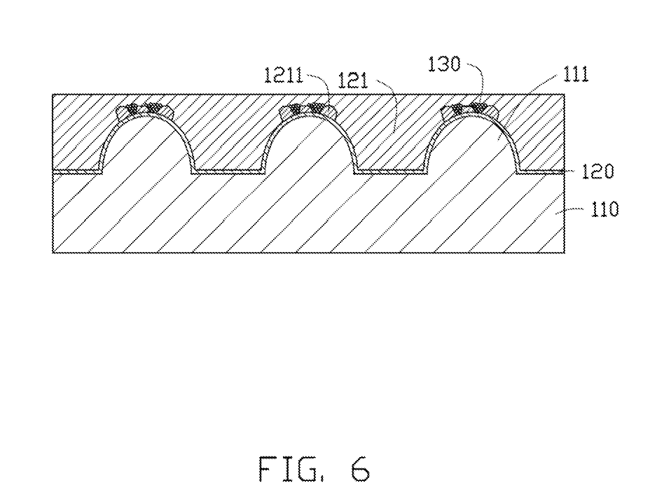

Referring to FIG. 1, a flowchart is presented in accordance with an embodiment of a method of manufacturing an LED die. The method 200 is provided by way of example, as there are a variety of ways to carry out the method. The method 200 described below can be carried out using the configurations illustrated in FIGS. 2-7, for example, and various elements of these figures are referenced in explaining the method 200. Each block shown in FIG. 1 represents one or more process, method, or subroutines, carried out in the method 200. Furthermore, the illustrated order of blocks is illustrative only and the order of the blocks can be changed. Additional blocks can be added or fewer blocks may be utilized without departing from this disclosure. The method 200 can begin at block 201.

At Block 201, a substrate 110 is provided with a plurality of protrusions formed on a surface 1101 thereof. The substrate 110 can be made of sapphire, silicon carbide (SiC), silicon (Si), gallium arsenide (GaAs), lithium metaaluminate (LiAlO₂), magnesium oxide (MgO), zinc oxide (ZnO), gallium nitride (GaN), aluminium nitride (AlN) or indium nitride (InN). In at least one embodiment, a cross section of each protrusion 111 can be arc-shaped. The protrusions 111 are spaced from each other. In other embodiments, the cross section of each protrusion 111 can be triangle, trapezoid or other polygons.

At Block 202, a first buffer layer 120 is formed on the surface 1101 of the substrate 110. The first buffer layer 120 covers the surface 1101 of the substrate 110, and also covers the protrusions 111. The first buffer layer 120 can be a low-temperature un-doped GaN layer. The first buffer layer 120 can have a uniform thickness. In at least one embodiment, the thickness of the first buffer layer 120 can be from 20 nm to 30 nm. A range of temperature of growing the first buffer layer 120 can be from 500° C. to 600° C.

At Block 203, a second buffer layer 121 is formed on the first buffer layer 120. The second buffer layer 121 is a high-temperature un-doped GaN layer. A range of temperature of growing the second buffer layer 121 can be from 1000° C. to 1100° C. The second buffer layer 121 dose not totally cover the first buffer layer 120 on the protrusions 111. The second buffer layer 121 covers the first buffer layer 120, except for some individual portions 1201 on top of the protrusions 111. Some portions 1201 of the first buffer layer 120 on the protrusions 111 are exposed through the second buffer layer 121. The second buffer layer 121 includes a first area 1211 and a second area 1212. The first area 1211 is defined upon the tops of the protrusions 111. The first area 1211 includes a small amount of un-doped GaN. The first area 1211 has a low surface flatness and a number of crystal defects. The second area 1212 is defined on the other portions of the first buffer layer 120 and between the protrusions 111. The second area 1212 has a high surface flatness and a small amount of crystal defects compared to the first area 1211.

At Block 204, nanospheres 130 are located upon the protrusions 111, covering the exposed portions 1201 of the first buffer layer 120. The nanospheres 130 can be made of SiO₂. A diameter of nanospheres 130 can be from 100 nm to 300 nm.

In at least one embodiment, the nanospheres 130 can be coated on the first buffer layer 120 by the following steps: floating the nanospheres 130 on an organic solvent; dipping the semi-finished product 170 into the same organic solvent; extracting the semi-finished product 170 from the organic solvent with the nanospheres 130 coated on the exposed portions 1201 of the first buffer layer 120; and removing the residual organic solvent on the semi-finished product 170. The organic solvent can be made of methylbenzene. The organic solvent can be volatile.

It can be understood that there are a small amount of nanospheres 130 left on the second area 1212. The leaved nanospheres 130 on the second area 1212 do not have a negative effect for a performance of the LED die.

At Block 205, the second buffer layer 121 can be formed to cover the nanospheres after the nanospheres 130 are coated on the first buffer layer 120.

At Block 206, a first semiconductor layer 140, an active layer 150 and a second semiconductor layer 160 can be formed on the second buffer layer 121 successively. In at least one embodiment, the first semiconductor layer 140 is an N-type doped semiconductor layer, and the second semiconductor layer 160 is a P-type doped semiconductor layer. The active layer 150 that is laminated on the first semiconductor layer 140, the active layer 150 may adopt a single quantum well structure, a multiple quantum well structure, or the like. In another embodiment, the first semiconductor layer 140 and the second semiconductor layer 160 can be a P-type doped semiconductor layer and an N-type doped semiconductor layer, respectively.

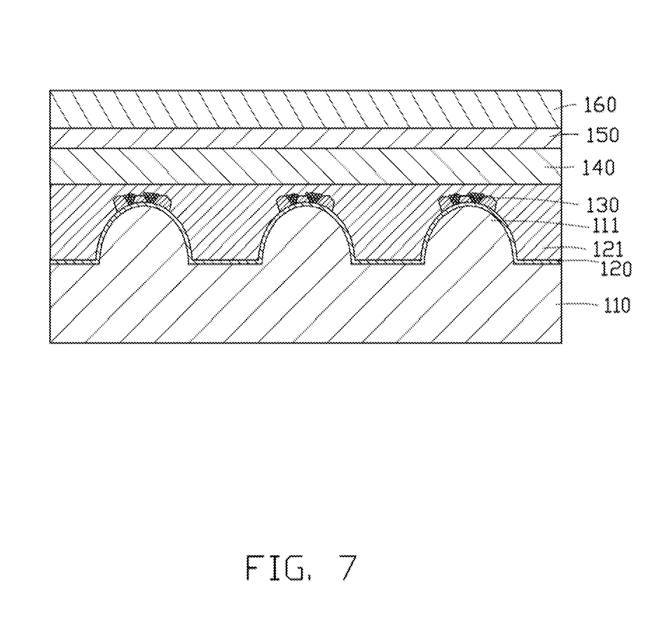

Referring to FIG. 7, an LED die is also provided in the present disclosure. The LED die comprises a substrate 110, a first buffer layer 120, a second buffer layer 121, a plurality of nanospheres 130, a first semiconductor layer 140, an active layer 150 and a second semiconductor layer 160. The first buffer layer 120, the second buffer layer 121, the first semiconductor layer 140, the active layer 150 and the second semiconductor layer 160 are formed successively on the substrate 110. The substrate 110 has a plurality of protrusions 111 on a surface 1101 of the substrate 110. The nanospheres 130 are located on the first buffer layer 120 formed on the protrusions 111 and covered by the second buffer layer 121.

The first buffer layer 120 is formed on the substrate 110. The first buffer layer 120 covers the surface 1101 of the substrate 110. The first buffer layer 120 can be a low-temperature un-doped GaN layer. The first buffer layer 120 can have a uniform thickness. The thickness of the first buffer layer 120 can be from 20 nm to 30 nm. A range of temperature of growing the first buffer layer 120 can be from 500° C. to 600° C. The second buffer layer 121 is formed on the first buffer layer 120 and covers the first buffer layer 120. The second buffer layer 121 is a high-temperature un-doped GaN layer. A range of temperature of growing the second buffer layer 121 can be from 1000° C. to 1100° C. The nanospheres 130 are located on a part of the first buffer layer 120 which is on the tops of the protrusions 111. The nanospheres 130 can be made of SiO₂. A diameter of nanospheres 130 can be from 100 nm to 300 nm.

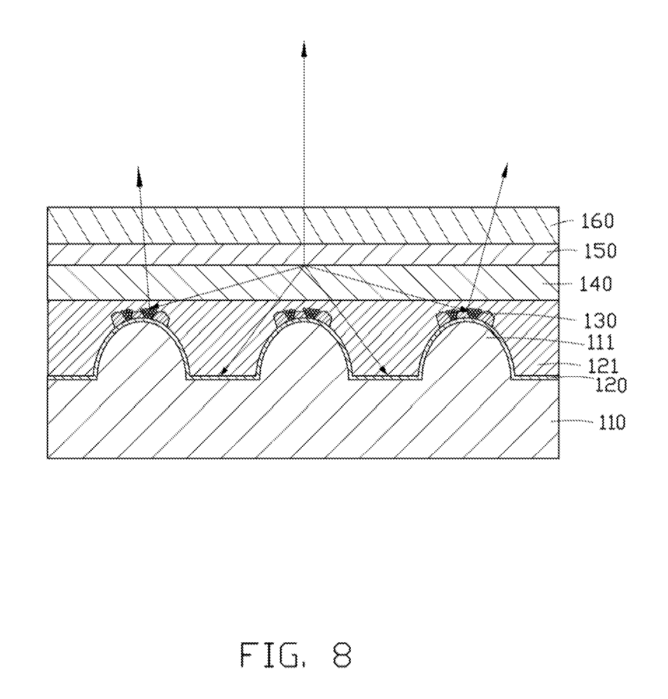

Referring to FIG. 8, light is emitted from the active layer 150. A part of light is emitted from the active layer 150, through the second semiconductor layer 160, to environment. A part of light emitted from the active layer 150 is through the first semiconductor 140 and the second buffer layer 121 to reach the nanospheres 130, and then this part of light are reflected by the nanospheres 130, and then this part of light are through the second buffer layer 121, the first semiconductor 140, the active layer 150 and the second semiconductor layer 160, finally to environment. A part of light is emitted from the active layer 150, through the first semiconductor 140 and the second buffer layer 121, to the first buffer layer 120, which is absorbed by the first buffer layer 120.

It is to be further understood that even though numerous characteristics and advantages have been set forth in the foregoing description of embodiments, together with details of the structures and functions of the embodiments, the disclosure is illustrative only; and that changes may be made in detail, including in matters of shape, size, and arrangement of parts within the principles of the disclosure to the full extent indicated by the broad general meaning of the terms in which the appended claims are expressed.

The embodiments shown and described above are only examples. Many details are often found in the art such as the other features of an LED die and a method of manufacturing the LED die. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A method of manufacturing an LED die comprising:
providing a substrate with a plurality of protrusions formed on a surface thereof;
forming a first buffer layer on the surface of the substrate;
forming a second buffer layer on the first buffer layer, the second buffer layer covers the first buffer layer, except for some individual portions on top of the protrusions;
locating nanospheres on the individual portions to cover the first buffer layer on the protrusions;
continuing to form the second buffer layer to cover the nanospheres; and
forming a first semiconductor layer, an active layer and a second semiconductor layer on the second buffer layer successively.

2. The method of claim 1, wherein the first buffer layer is a low-temperature un-doped GaN layer.

3. The method of claim 1, wherein the first buffer layer has a uniform thickness.

4. The method of claim 3, wherein the thickness of the first buffer layer is from 20 nm to 30 nm.

5. The method of claim 1, wherein the second buffer layer is a high-temperature un-doped GaN layer.

6. The method of claim 1, wherein the nanospheres is made of SiO₂.

7. The method of claim 1, wherein a diameter of nanospheres is from 100 nm to 300 nm.

8. The method of claim 1, wherein locating the nanospheres on the individual portions to cover the first buffer layer on the protrusions comprises:
floating the nanoshperes on an organic solvent;
dipping a semi-finished product manufactured after “forming a second buffer layer on the first buffer layer, the second buffer layer being not totally covering the first buffer layer on the protrusions and being exposing portion of the first buffer layer on the protrusions” into the organic solvent;
extracting the semi-finish product from the organic solvent; and
removing the residual organic solvent on the semi-finish product.

9. The method of claim 8, wherein the organic solvent is made of methylbenzene.

10. The method of claim 8, wherein the organic solvent is volatile.

11. An LED die comprising:
a substrate with a plurality of protrusions formed on a surface thereof;
a first buffer layer formed on the surface of the substrate ;
a second buffer layer formed on the first buffer layer, the second buffer layer covering the first buffer layer; nanospheres located on a part of the first buffer layer which is located on tops of the protrusions and covered by the second buffer layer; and
a first semiconductor layer, an active layer and a second semiconductor layer formed on the second buffer layer successively.

12. The LED die of claim 11, wherein the first buffer layer is a low-temperature un-doped GaN layer.

13. The LED die of claim 11, wherein the first buffer layer has a uniform thickness.

14. The LED die of claim 13, wherein the thickness of the first buffer layer is from 20 nm to 30 nm.

15. The LED die of claim 11, wherein the second buffer layer is a high-temperature un-doped GaN layer.

16. The LED die of claim 11, wherein the nanospheres is made of SiO₂.

17. The LED die of claim 11, wherein a diameter of nanospheres is from 100 nm to 300 nm.
